(19) United States
(12) Patent Application Publication
(10) Pub. No.: US 2021/0271130 A1
(43) Pub. Date: Sep. 2, 2021

(54) POLARIZATION ASSEMBLY AND DISPLAY DEVICE

(71) Applicant: WUHAN CHINA STAR OPTOELECTRONICS SEMICONDUCTOR DISPLAY TECHNOLOGY CO., LTD., Wuhan, Hubel (CN)

(72) Inventor: Jianjian MAO, Wuhan, Hubei (CN)

(21) Appl. No.: 16/309,207

(22) PCT Filed: Nov. 29, 2018
(86) PCT No.: PCT/CN2018/118068

§ 371 Date: Dec. 12, 2018

(30) Foreign Application Priority Data
Sep. 20, 2018 (CN) 201811100195.1

(51) Int. Cl. G02F 1/1335; G02F 1/139

(52) U.S. Cl. CPC G02F 1/133528; G02F 1/133512; G02F 1/133502; G02F 1/1393

(57) ABSTRACT

A polarization assembly and a display device are provided. The polarization assembly includes a polarizer and an optical clear adhesive. The optical clear adhesive is disposed on at least one side surface of the polarizer, and the polarizer and the optical clear adhesive are formed integrally into one piece. During manufacture of the display apparatus, merely bonding the polarizer of the polarization assembly to the display apparatus and then bonding the protective layer or the touch device to the optical clear adhesive to complete manufacture of the display apparatus, which simplifies the bonding process.

### FIELD OF INVENTION

The present invention relates to a field of display technology, especially to a polarization assembly and a display device.

### BACKGROUND OF INVENTION

Conventional display apparatuses such as liquid crystal displays (LCDs) and organic light-emitting diode (OLED, also called organic electro-luminescence) displays all need to employ a polarizer to control liquid crystal for adjustment of intensity of light.

To fabricate a display apparatus, it is necessary to further dispose a protective layer or a touch device outside the display apparatus to form an electronic apparatus, such as a monitor, cell phone or all in one (AIO) computer. When the protective layer or the touch device is further disposed outside and contacts a polarizer of the display apparatus, a contact interface has an air gap and therefore causes phenomenon of Newton's rings.

To prevent or reduce the air gap, a conventional technology disposes an optical clear adhesive between the protective layer or the touch device and the polarizer. Specifically, the polarizer is bonded to the display apparatus by a roller bonding process, and then the optical clear adhesive is bonded to the protective layer or the touch device by the roller bonding process. Finally, the polarizer is bonded to the optical clear adhesive. The above technology requires implementation of 3 times of the bonding steps to finish the bonding process. Therefore, the bonding process is complicated and increases manufacturing cost of the display apparatus.

In other words, the conventional display apparatus has the technical issue that the bonding process for the polarizer and the optical clear adhesive is complicated.

### SUMMARY OF INVENTION

The present invention provides a polarization assembly and display device to solve an issue that a conventional bonding process for a polarizer and an optical clear adhesive of a display apparatus is complicated.

To solve the above issue, technical solutions provided by the present invention are as follows.

An embodiment of the present invention provides a polarization assembly, comprising:

a polarizer; and

an optical clear adhesive disposed on at least one side surface of the polarizer;

wherein the polarizer and the optical clear adhesive are formed integrally into one piece.

In the polarization assembly of the present invention, the optical clear adhesive comprises a first optical clear adhesive, and the first optical clear adhesive is disposed on a side surface of the polarizer.

In the polarization assembly of the present invention, the polarization assembly further comprises:

a protective film disposed on a surface of the polarizer facing away from the first optical clear adhesive; and

a first release film disposed on a surface of the first optical clear adhesive facing away from the polarizer.

In the polarization assembly of the present invention, the optical clear adhesive comprises a second optical clear adhesive and a third optical clear adhesive, and the second optical clear adhesive and the third optical clear adhesive are disposed on two opposite side surfaces of the polarizer respectively.

In the polarization assembly of the present invention, the polarization assembly further comprises:

a second release film disposed on a surface of the second optical clear adhesive facing away from the polarizer; and

a third release film disposed on a surface of the third optical clear adhesive facing away from the polarizer.

In the polarization assembly of the present invention, the optical clear adhesive comprises a light shielding region and a light transmission region, and the light shielding region surrounds the light transmission region.

In the polarization assembly of the present invention, the light shielding region is distributed with a light shielding colorant.

In the polarization assembly of the present invention, the light shielding colorant is a decomposed colorant.

In the polarization assembly of the present invention, the polarizer comprises:

a body; and

a protruding structure formed on at least one side surface of the body;

wherein the protruding structure comprises a plurality of protrusions in nanoscale, a refractive index of a surface of each protrusion varies in continuous gradient.

In the polarization assembly of the present invention, the polarizer further comprises a bottom coating layer, the bottom coating layer is disposed between the protrusions and a surface of the body, the bottom coating layer is disposed on the surface of the body, and the protrusions are distributed on the bottom coating layer at intervals.

An embodiment of the present invention provides a display device comprising a display panel, a polarization assembly disposed on the display panel, and a touch panel disposed on the polarization assembly, wherein the polarization assembly comprises:

a polarizer; and

an optical clear adhesive disposed on at least one side surface of the polarizer;

wherein the polarizer and the optical clear adhesive are formed integrally into one piece.

In the display device of the present invention, the optical clear adhesive comprises a second optical clear adhesive and a third optical clear adhesive, and the second optical clear adhesive and the third optical clear adhesive are disposed on two opposite side surfaces of the polarizer respectively.

In the display device of the present invention, the optical clear adhesive comprises a light shielding region and a light transmission region, and the light shielding region surrounds the light transmission region.

In the display device of the present invention, the light shielding region is distributed with a light shielding colorant.

In the display device of the present invention, the light shielding colorant is a decomposed colorant.

An embodiment of the present invention provides a display device comprising a display panel, a polarization assembly on the display panel, a cover plate disposed on the polarization assembly, wherein the polarization assembly comprises:

a polarizer; and

an optical clear adhesive disposed on at least one side surface of the polarizer;

wherein the polarizer and the optical clear adhesive are formed integrally into one piece.

In the display device of the present invention, the optical clear adhesive comprises a second optical clear adhesive and a third optical clear adhesive, the second optical clear adhesive and the third optical clear adhesive are disposed on two opposite side surfaces of the polarizer.

In the display device of the present invention, the optical clear adhesive comprises a light shielding region and a light transmission region, and the light shielding region surrounds the light transmission region.

In the display device of the present invention, the polarizer wherein the polarizer comprises:

a body; and

a protruding structure formed on at least one side surface of the body;

wherein the protruding structure comprises a plurality of protrusions in nanoscale, a refractive index of a surface of each protrusion varies in continuous gradient.

In the display device of the present invention, the polarizer further comprises a bottom coating layer, the bottom coating layer is disposed between the protrusions and a surface of the body, the bottom coating layer is disposed on the surface of the body, and the protrusions are distributed on the bottom coating layer at intervals.

Advantages of the present invention are as follows. The present invention provides a new polarization assembly and display device comprising a polarizer, an optical clear adhesive, the optical clear adhesive disposed on at least one side surface of the polarizer, and the polarizer and the optical clear adhesive are formed integrally into one piece. Therefore, the polarization assembly can realize polarization to light based on the polarizer. The optical clear adhesive can prevent gaps between the polarizer and the protective layer or the touch device. Also, during manufacture of the display apparatus, merely bonding the polarizer of the polarization assembly to the display apparatus and then bonding the protective layer or the touch device to the optical clear adhesive to complete manufacture of the display apparatus, which simplifies the bonding process and solve the issue that the conventional bonding process of the display apparatus is complicated.

### DESCRIPTION OF DRAWINGS

To more clearly elaborate on the technical solutions of embodiments of the present invention or prior art, appended figures necessary for describing the embodiments of the present invention or prior art will be briefly introduced as follows. Apparently, the following appended figures are merely some embodiments of the present invention. A person of ordinary skill in the art may acquire other figures according to the appended figures without any creative effort.

FIG. 1 is a first schematic view of a polarization assembly provided by an embodiment of the present invention;

FIG. 2 is a first schematic view of a manufacturing apparatus provided by an embodiment of the present invention;

FIG. 3 is a first schematic view of a manufacturing process for a polarization assembly provided by an embodiment of the present invention;

FIG. 4 is a second schematic view of a polarization assembly provided by an embodiment of the present invention;

FIG. 5 is a second schematic view of a manufacturing apparatus provided by an embodiment of the present invention;

FIG. 6 is a second schematic view of a manufacturing process for a polarization assembly provided by an embodiment of the present invention;

FIG. 7 is a third schematic view of a polarization assembly provided by an embodiment of the present invention;

FIG. 8 is a third schematic view of a manufacturing process for a polarization assembly provided by an embodiment of the present invention;

FIG. 9 is a fourth schematic view of a polarization assembly provided by an embodiment of the present invention;

FIG. 10 is a first schematic view of a display device provided by an embodiment of the present invention; and

FIG. 11 is a second schematic view of a display device provided by an embodiment of the present invention.

### DETAILED DESCRIPTION OF PREFERRED EMBODIMENTS

Each of the following embodiments is described with appending figures to illustrate specific embodiments of the present invention that are applicable. The terminologies of direction mentioned in the present invention, such as “upper”, “lower”, “front”, “rear”, “left”, “right”, “inner”, “outer”, “side surface”, etc., only refer to the directions of the appended figures. Therefore, the terminologies of direction are used for explanation and comprehension of the present invention, instead of limiting the present invention. In the figures, units with similar structures are marked with the same reference characters.

The present invention aims at the technical issue that a conventional display apparatus has a complicated bonding process. Embodiments of the present invention can solve the defects.

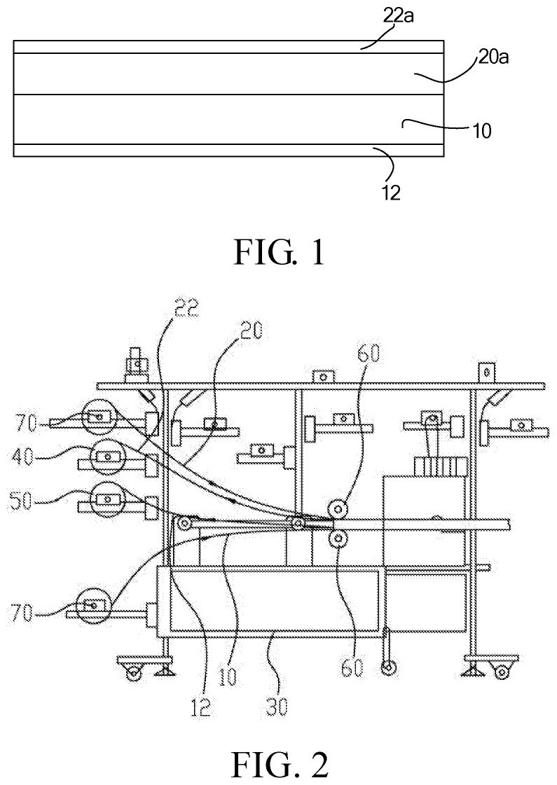

With reference to FIG. 1, the present invention provides a polarization assembly comprising a polarizer 10 and an optical clear adhesive 20 (including the optical clear adhesives 20a, 20b, 20c in the figures). The optical clear adhesive 20 is disposed on at least one side surface of the polarizer 10. The polarizer 10 and the optical clear adhesive 20 are formed integrally into one piece.

The polarization assembly provided by the present embodiment comprises a polarizer and an optical clear adhesive. The optical clear adhesive is disposed on at least one side surface of the polarizer, and the polarizer and the optical clear adhesive are formed integrally into one piece. Therefore, the polarization assembly can realize polarization to light based on the polarizer. The optical clear adhesive can prevent gaps between the polarizer and the protective layer or the touch device. Also, during manufacture of the display apparatus, merely bonding the polarizer of the polarization assembly to the display apparatus and then bonding the protective layer or the touch device to the optical clear adhesive to complete manufacture of the display apparatus, which simplifies the bonding process and solve the issue that the conventional bonding process of the display apparatus is complicated.

In an embodiment, as shown in FIG. 1, the optical clear adhesive 20 comprises a first optical clear adhesive 20a. The first optical clear adhesive 20a is disposed on a side surface of the polarizer 10.

In an embodiment, as shown in FIG. 1, the polarization assembly further comprises:

a protective film 12 disposed on a surface of the polarizer 10 facing away from the first optical clear adhesive 20a; and

a first release film 22a (distinguishing term is used for the convenience of description, and it can be collectively referred to as release film 22) disposed on a surface of the first optical clear adhesive 20a facing away from the polarizer 11.

In an embodiment, first optical clear adhesive 20a is an optical clear adhesive (OCA).

The polarization assembly is sold to a buyer, the buyer by tearing down the release film 22 can attach a touch panel or a glass cover plate to the optical clear adhesive 20. The buyer by tearing down the protective film 12 can attach a display apparatus under the polarizer 10.

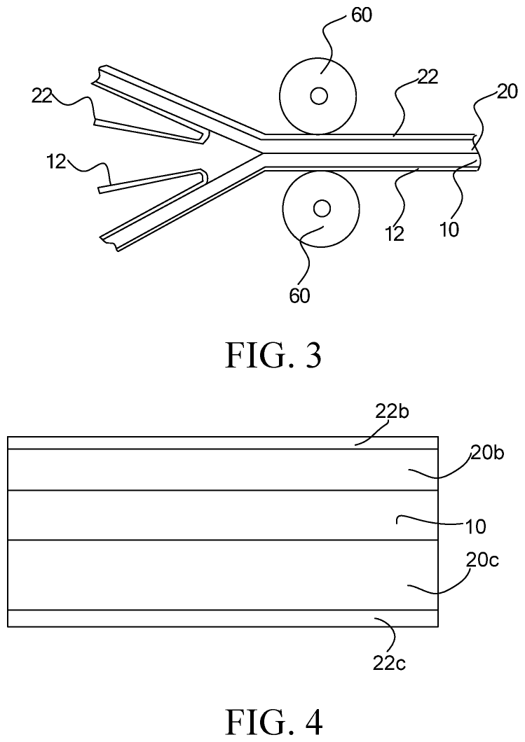

With reference to FIG. 2 and FIG. 3, a polarization assembly manufacturing apparatus of the present invention comprises a frame 30, a roller 40 disposed rotatably on the frame 30, a roller shaft 50, and two wheels 60. The two wheels 60 are aligned with each other along a vertical direction. Axes of the two wheels 60 are parallel to each other. A distance between the two wheels 60 corresponds to a thickness of the optical clear adhesive 20 and a polarizer 10. The two wheels 60 can cooperate with each other to roll and compress the optical clear adhesive 20 and the polarizer 10 to make the optical clear adhesive 20 to be fitted on the polarizer 10. The two wheels 60 has the same line speed. The manufacturing apparatus further comprises two suspension rods 70, the two suspension rods 70 are configured to hang the polarizer 10 and the optical clear adhesive 20 respectively.

Before producing the polarization assembly, the polarizer 10 and the optical clear adhesive 20 are two individual elements. An upper side and a lower side of the polarizer 10 are adhered with protective films 12 respectively, and an upper side and a lower side of the optical clear adhesive 20 are adhered with release films 22.

With reference FIGS. 1 to 3, production is implementation as follows.

First, one end of a release film 22 adhered on a lower surface of the optical clear adhesive 20 is torn off and wrapped on the roller 40. The roller 40 rotates to tear off the release film 22 from the optical clear adhesive 20, one end of the protective film 12 adhered on the surface of the polarizer 10 is torn off and wrapped on the roller shaft 50, the roller shaft 50 rotates to tear off the protective film 12 from the polarizer 10.

Then, optical clear adhesive 20 and the polarizer 10 are stacked together and extend through the two wheels 60 aligned with each other along the vertical direction. The two wheels 60 cooperate with each other to roll and compress the optical clear adhesive 20 and the polarizer 10 to fit the optical clear adhesive 20 on the polarizer 10. The polarizer 10 and the optical clear adhesive 20 are formed integrally into one piece. A plane on which the two wheels 60 lie is perpendicular to the one piece formed integrally by the polarizer 10 and the optical clear adhesive 20.

Finally, trimming and grinding processes are implemented to acquire a final polarization assembly.

In an embodiment, as shown in FIG. 4, the optical clear adhesive 20 comprises a second optical clear adhesive 20b and a third optical clear adhesive 20c. The second optical clear adhesive 20b and the third optical clear adhesive 20c are disposed on two opposite side surfaces of the polarizer 10 respectively.

In an embodiment, as shown in FIG. 4, the polarization assembly further comprises:

a second release film 22b disposed on a surface of the second optical clear adhesive 20b facing away from the polarizer; and

a third release film 22c, disposed on a surface of the third optical clear adhesive 20c facing away from the polarizer.

In an embodiment, second optical clear adhesive 20b is an optical clear adhesive, third optical clear adhesive 20c is a pressure sensitive adhesive (PSA).

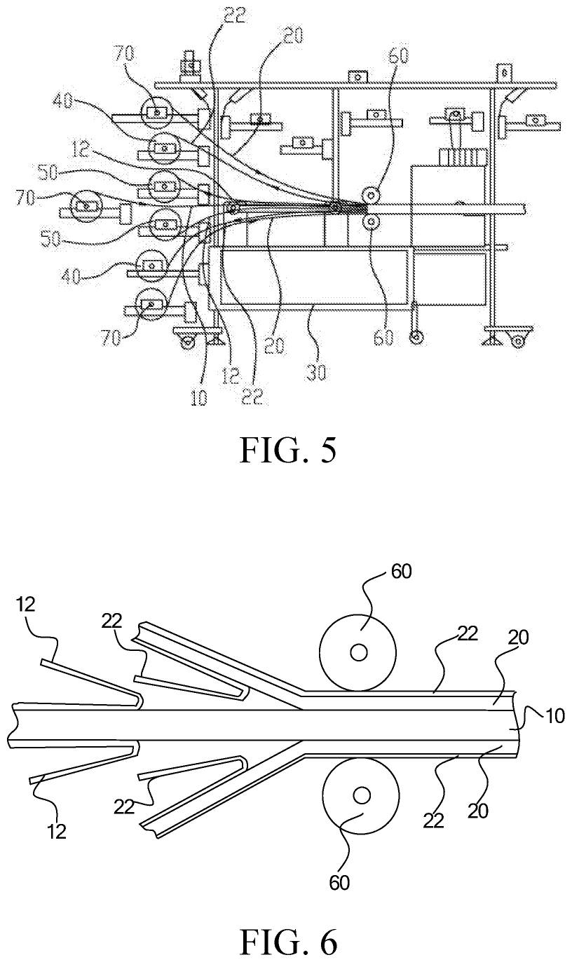

With reference to FIGS. 5 and 6, to produce the polarization assembly as shown in FIG. 4, it is only required to add a roller 40, a roller shaft 50 and a suspension rod 70 on the original apparatus. In other words, the manufacturing apparatus comprises a frame 30 and two rollers 40 disposed rotatably on the frame 30, two roller shafts 50, two wheels 60, three suspension rods 70. Furthermore, a distance between the two wheels 60 corresponds to a thickness of two optical clear adhesives 20 and one polarizer 10. Therefore, during the production, two optical clear adhesives 20 and a polarizer 10 are hung on three suspension rod 70 respectively.

First, one end of a release film 22 adhered to a lower surface of an optical clear adhesive 20 is torn off and wrapped on a roller 40. One end of the release film 22 adhered to an upper surface of another optical clear adhesive 20 is torn off and wrapped on another roller 40. The roller 40 rotates and tears off the release film 22 from the optical clear adhesive 20. One end of the protective film 12 adhered to an upper surface of the polarizer 10 is torn off and wrapped on a roller shaft 50. One end of the protective film 12 adhered to a lower surface of the polarizer 10 is torn off and wrapped on another roller shaft 50. The roller shaft 50 rotates and tears off the protective film 12 from the polarizer 10.

Then, the polarizer 10 is set between the two optical clear adhesives 20, and the optical clear adhesive 20, the polarizer 10 and the optical clear adhesive 20 extends through the two wheels 60 aligned with each other along the vertical direction. The two wheels 60 cooperate with each other to roll and compress the optical clear adhesives 20 and the polarizer 10. The two optical clear adhesives 20 are fitted on the upper surface and the lower surface of the polarizer 10. The polarizer 10 and the two optical clear adhesive 20 are formed integrally into one piece.

Finally, trimming and grinding processes are implemented to acquire a final polarization assembly.

In an embodiment, the optical clear adhesive 20 is acquired by applying a coating process to the polarizer 10.

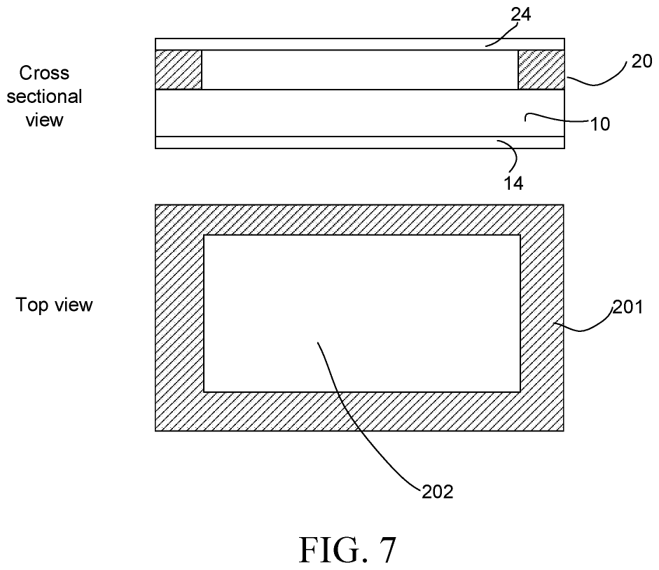

In an embodiment, as shown in FIG. 7, the optical clear adhesive 20 comprises a light shielding region 201 and a light transmission region 202, the light shielding region 201 surrounds the light transmission region 202.

In an embodiment, the light shielding region 201 is distributed with a light shielding colorant such as a decomposed colorant.

Therefore, the polarization assembly has a thinner thickness, can be formed integrally into one piece by a roll to roll process, and is suitable for batch manufacture to significantly lower the cost.

For ease of understanding, a brief description of the flexible polarizer according to an embodiment of the present invention will be first made below.

A conventional technology needs to implement an ink patterning process on a rear of the cover plate to form a black matrix. Because the ink patterning process generate uneven and rugged surface on the cover plate, the polarizer and the cover plate cannot be formed integrally into one piece through the roll to roll process. The present embodiment, by injecting the decomposed colorant into the optical clear adhesive of the polarization assembly, makes the optical clear adhesive have the light transmission region and the light shielding region such that the optical clear adhesive can serve as a regular optical clear adhesive while serving as a black matrix including a light shielding function. Therefore, a thickness of the display is reduced and the roll to roll process can be used to integrally form one piece to achieve batch production and lowered cost.

In an embodiment, decomposed colorant can be a nanoscale exposure decomposed colorant. Therefore, exposing a specific region of the optical clear adhesive doped with the decomposed colorant can obtain an optical clear adhesive with a light transmission region and a light shielding region. A person of ordinary skill in the art can understand that the decomposed colorant is an opaque material. A color of the decomposed colorant is not limited. In an embodiment, the decomposed colorant can be white or black.

With reference to FIG. 7, the light shielding region 201 in the optical clear adhesive 20 surrounds the light transmission region 202. wherein light shielding region 201 can achieve light shielding function by employing the colored decomposed colorant. A person of ordinary skill in the art can understand that to form the optical clear adhesive, a colored decomposed colorant can be added into an entire film layer, and later, portions of the decomposed colorant in the light transmission region 201 is decomposed to acquire a transparent optical clear adhesive. Therefore, the light shielding region of the optical clear adhesive can have a black matrix function, which can omit the black matrix on the rear of the cover plate and reduce its thickness.

In an embodiment, the light transmission region 201 in the optical clear adhesive can correspond to a displaying region in the display device, light shielding region 202 can correspond to a non-displaying region in the display device. Cost of the display device can be decreased.

Also, the present embodiment providing a manufacturing method comprising the following steps.

Step 1 comprises providing a polarizer.

A way for forming the polarizer is unlimited, and a person of ordinary skill in the art can design based on specific conditions. For example, according to an embodiment of the present invention, the polarizer can be formed by stretching or coating. A person of ordinary skill in the art can understand that the polarizer can include a poly vinyl alcohol (PVA) thin film, the thin film has a polarization function and is a core portion of the polarizer that decides optical indexes such as polarization performance of the polarizer, light transmittance, color tune, etc.

Step 2 comprises disposing an optical clear adhesive on the polarizer, wherein optical clear adhesive comprises a light transmission region and a light shielding region.

The optical clear adhesive comprises a light transmission region and a light shielding region. Therefore, the optical clear adhesive can serve as an optical clear adhesive while serving as a black matrix having a light shielding function, which reduces a thickness of the flexible polarizer, realizes batch production and lowers the cost.

In an embodiment, optical clear adhesive is disposed on the polarizer by a roll to roll process. Therefore, the black matrix can be disposed in the flexible polarizer by the roll to roll process, which omits an ink patterning process, realizes batch production and lowers the cost.

In an embodiment, the optical clear adhesive is doped with a decomposed colorant, by using characteristics of decomposition opaque of the decomposed colorant, a decomposed region of the decomposed colorant in the optical clear adhesive corresponds to the light transmission region, a non-decomposed region of the decomposed colorant corresponds to the light shielding region. Therefore, an optical clear adhesive simultaneously with protection function and light shielding function can be acquire by a simple way, which reduces the thickness, employs the roll to roll process to perform integral formation, realizes batch production and lowers the cost.

In an embodiment, the polarizing member can be made by steps as follows. First, an optical clear adhesive doped with a decomposed colorant is disposed on the polarizer. Specifically, the optical clear adhesive doped with the decomposed colorant can be disposed the polarizer by the roll to roll process. Later, according to a predetermined mask plate, a predetermined region of a flexible transparent thin film doped with the decomposed colorant is exposed to decompose the decomposed colorant in a region corresponding to the light transmission region. Therefore, an optical clear adhesive including a light transmission region and a light shielding region is formed.

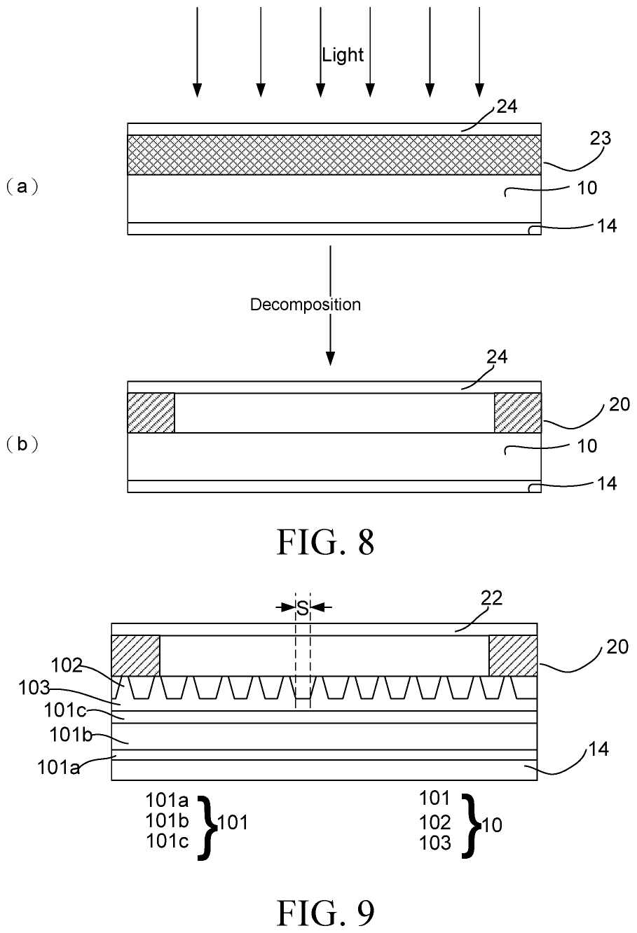

Specifically, with reference to FIG. 8, First, an opaque optical clear adhesive 23 doped with a decomposed colorant is disposed on a polarizer 10 by a roll to roll process. Later, a side of the opaque optical clear adhesive 23 doped with the decomposed colorant facing away from polarizer 10 is disposed with a hardened layer 24, and a side of the polarizer 10 facing away from the optical clear adhesive 23 doped with the decomposed colorant is disposed with an optical transparent pressure sensitive adhesive 14. Later, the optical clear adhesive 23 doped with the decomposed colorant is exposed through the hardened layer 24, as shown in FIG. 8 (a), to form an optical clear adhesive 20 including a light transmission region and a light shielding region, and to further form a polarizer with a thinner thickness and a lower cost, as shown in FIG. 8 (b). a sequence of disposing the optical transparent pressure sensitive adhesive and exposing process is not limited. In other words, the optical transparent pressure sensitive adhesive can be disposed first and, or alternatively, the flexible transparent thin film doped with the decomposed colorant can be indirectly exposed first.

In an embodiment, hardened layer can also be formed by a fingerprint-proof material. Therefore, the flexible polarizer can have a fingerprint-proof function. According to an embodiment of the present invention, the hardened layer can be formed by Polytetrafluoroethylene (PTFE).

In an embodiment, with reference to FIG. 9, the polarizer 10 comprises a body 101 and a protruding structure 102 formed on at least one side surface of the body 101. The protruding structure 102 comprises a plurality of protrusions in nanoscale, and a refractive index of each protrusion surface varies in continuous gradient.

In an embodiment, as shown in FIG. 9, the polarizer 10 also comprises a bottom coating layer 103. The bottom coating layer 103 is disposed between the protrusion and a surface of the body. The bottom coating layer is disposed on the surface of the body. The protrusions are distributed on the bottom coating layer at intervals.

In an embodiment, body 101 comprises tri-acetate cellulose (TAC) layer 101a, poly vinyl alcohol (PVA) layer 101b and tri-acetate cellulose (TAC) layer 101c that are sequentially stacked.

In an embodiment, at least one of the TAC layer 101a and the TAC layer 101c can also be a coefficient of performance (COP) layer of an optical material.

In an embodiment, the protruding structure 102 and the bottom coating layer 103 are formed integrally, and can be made by transparent material without affecting the entire light transmittance. The material can be solvent-free UV-curing acrylic resin or thermosetting resin.

In an embodiment, a thickness of the bottom coating layer 103 is 0.5 μm-4.5 μm.

In an embodiment, protruding structure 102 are plural in nanoscale.

In an embodiment, a surface of the protruding structure 102 is a continuously curved surface.

In an embodiment, a plurality of protruding structures 102 are distributed on the surface of the body 101 at intervals, and a structural dimension of each protrusion 123 is less than a wavelength of a visible light.

In an embodiment, a refractive index of the surface of the protruding structure 102 varies in continuous gradient.

In an embodiment, protruding structure 102 is one of a cone, a semi-ellipsoid and a truncated cone or a combination thereof.

In an embodiment, a height of the protruding structure 102 is greater than or equal to a diameter of the protruding structure 102 such that anti-reflection characteristic thereof is better.

In an embodiment, the protruding structure 102 and the bottom coating layer 103 are ultraviolet (UV)glue imprint structure. The UV glue is a UV curing glue. First, the body 101 is coated with a layer of UV glue layer. A transfer mold is disposed on the UV glue layer, a certain distance is between the transfer mold and the UV glue layer, and the transfer mold is evenly distributed with a plurality of recesses. The transfer mold rotates, imprints the UV glue layer. Furthermore, UV light cures the UV glue layer on another side of the body 101.

A distance between the transfer mold and the TAC layer is a thickness of the bottom coating layer 103. The recesses correspond to the protruding structure 102. A shape of the protruding structure 102 conforms with shapes of the recesses. The above manufacturing process of the protruding structure 102 is simple, is easy to operate, and is convenient for promotion and application of the technology.

In an embodiment, a diameter of the protruding structure 102 is 50 nm-400 nm.

In an embodiment, a height of the protruding structure 102 is 100 nm-400 nm.

In an embodiment, an edge distance S between adjacent two of the protruding structures 102 is 50 nm-500 nm.

In an embodiment, the bottom coating layer 103 can be omitted. When the bottom coating layer 103 is omitted, the protruding structure 102 is a gravure printing structure. The gravure is disposed with a plurality of conical recesses, the conical recesses are distributed evenly on an outer surface of the gravure. The resin material is coated on the gravure, and a scraper scrapes redundant resin material to make the conical recesses be filled with the resin material. Furthermore, the UV light cures the resin material on another side of the polarizer. The gravure rotates to form the conical protruding structures 102 on the polarizer. Because a height of the protruding structure 102 is greater than a diameter of the protruding structure 102, the protruding structure 102 can be formed well and is easy to manufacture.

By disposing the protruding structures 102 with the structural dimension of each protruding structure 102 less than the wavelength of the visible light, the light wave cannot identify the protruding structures 102, therefore, a refractive index of the surface of the polarizer 10 continuously varies along a depth direction, which reduces reflection phenomenon due to dramatical change of the refractive index and an optical anti-reflection effect of the polarizer is better.

The present invention also provides a display apparatus, display apparatus comprising the above polarization assembly. The above polarization assembly is applied to display apparatuses such as touch smart phones, TVs, etc. The display apparatus with the above polarization assembly has a thinner case, a higher light transmittance, a lower reflection index, a higher light usage rate, and therefore performance of the display apparatus can be improved.

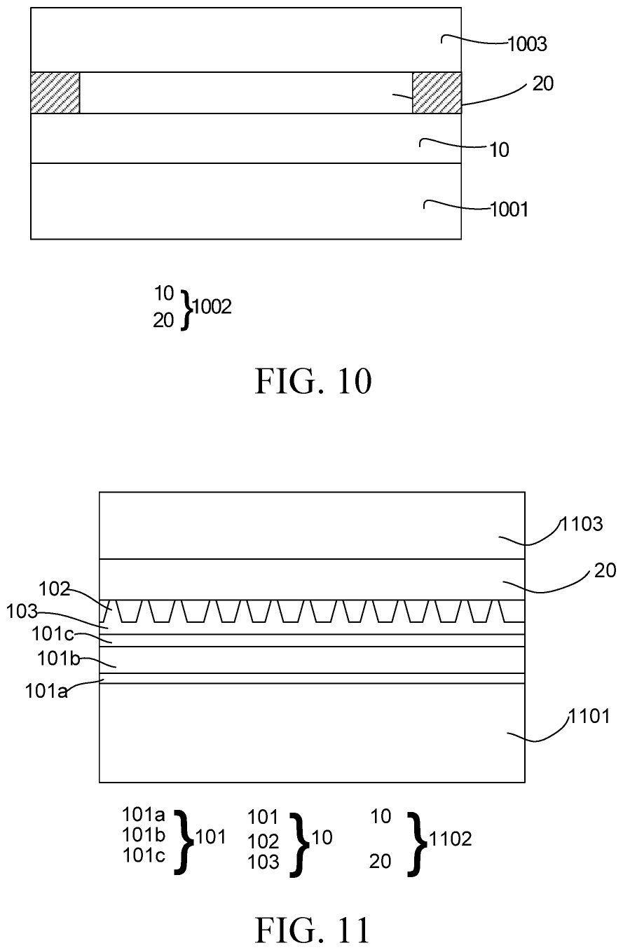

In an embodiment, as shown in FIG. 10, the display device provided by the embodiment of the present invention comprises a display panel 1001, a polarization assembly 1002 disposed on the display panel, and a touch panel 1003 disposed on the polarization assembly. The polarization assembly 1002 comprises a polarizer 10 and an optical clear adhesive 20 (including the optical clear adhesive 20a, 20b, 20c in the figures). The optical clear adhesive 20 is disposed on at least one side surface of the polarizer 10. The polarizer 10 and the optical clear adhesive 20 are formed integrally into one piece.

In an embodiment, as shown in FIG. 4, the optical clear adhesive 20 comprises a second optical clear adhesive 20b and a third optical clear adhesive 20c. The second optical clear adhesive 20b and the third optical clear adhesive 20c are disposed on two opposite side surfaces of the polarizer 10.

In an embodiment, as shown in FIG. 7, the optical clear adhesive 20 comprises a light shielding region 201 and a light transmission region 202. The light shielding region 201 surrounds the light transmission region 202.

In an embodiment, the light shielding region 201 is distributed with light shielding colorant such as a decomposed colorant.

In an embodiment, as shown in FIG. 11, an embodiment of the present invention provides a display device comprising a display panel 1101, a polarization assembly 1102 disposed on the display panel, and a cover plate 1103 disposed on the polarization assembly. The polarization assembly 1102 comprises a polarizer 10 and an optical clear adhesive 20 (including the optical clear adhesive 20a, 20b, 20c shown in the figures). The optical clear adhesive 20 is disposed on at least one side surface of the polarizer 1. The polarizer 10 and the optical clear adhesive 20 are formed integrally into one piece.

In an embodiment, as shown in FIG. 4, the optical clear adhesive 20 comprises a second optical clear adhesive 20b and a third optical clear adhesive 20c. The second optical clear adhesive 20b and the third optical clear adhesive 20c are disposed on two opposite side surfaces of the polarizer 10 respectively.

In an embodiment, as shown in FIG. 7, the optical clear adhesive 20 comprises a light shielding region 201 and the light transmission region 202. the light shielding region 201 surrounds the light transmission region 202.

In an embodiment, as shown in FIG. 9, the polarizer 10 comprises: a body 101; and a protruding structure 102 is formed on at least one side surface of the body 101. The protruding structure comprises a plurality of protrusions in nanoscale, and a refractive index of each protrusion surface varies in continuous gradient.

In an embodiment, as shown in FIG. 9, the polarizer 10 further [symbol] comprises a bottom coating layer 103, the bottom coating layer 103 is disposed between the protrusion and a surface of the body, the bottom coating layer is disposed on the surface of the body surface, and the protrusions are distributed on the bottom coating layer at intervals.

According to the above-mentioned embodiments, the following conclusion is given.

The present invention provides a new polarization assembly and display device comprising a polarizer and an optical clear adhesive. The optical clear adhesive is disposed on at least one side surface of the polarizer, and the polarizer and the optical clear adhesive are formed integrally into one piece. Therefore, the polarization assembly can realize polarization to light based on the polarizer. The optical clear adhesive can prevent gaps between the polarizer and the protective layer or the touch device. Also, during manufacture of the display apparatus, merely bonding the polarizer of the polarization assembly to the display apparatus and then bonding the protective layer or the touch device to the optical clear adhesive to complete manufacture of the display apparatus, which simplifies the bonding process and solve the issue that the conventional bonding process of the display apparatus is complicated.

Although the preferred embodiments of the present invention have been disclosed as above, the aforementioned preferred embodiments are not used to limit the present invention. The person of ordinary skill in the art may make various changes and modifications without departing from the spirit and scope of the present invention. Therefore, the scope of protection of the present invention is defined by the scope of the claims.

What is claimed is:

1. A polarization assembly, comprising:
a polarizer; and
an optical clear adhesive disposed on at least one side surface of the polarizer;
wherein the polarizer and the optical clear adhesive are formed integrally into one piece.

2. The polarization assembly as claimed in claim 1, wherein the optical clear adhesive comprises a first optical clear adhesive, and the first optical clear adhesive is disposed on a side surface of the polarizer.

3. The polarization assembly as claimed in claim 2, wherein the polarization assembly further comprises:
a protective film disposed on a surface of the polarizer facing away from the first optical clear adhesive; and
a first release film disposed on a surface of the first optical clear adhesive facing away from the polarizer.

4. The polarization assembly as claimed in claim 1, wherein the optical clear adhesive comprises a second optical clear adhesive and a third optical clear adhesive, and the second optical clear adhesive and the third optical clear adhesive are disposed on two opposite side surfaces of the polarizer respectively.

5. The polarization assembly as claimed in claim 4, wherein the polarization assembly further comprises:
a second release film disposed on a surface of the second optical clear adhesive facing away from the polarizer; and
a third release film disposed on a surface of the third optical clear adhesive facing away from the polarizer.

6. The polarization assembly as claimed in claim 1, wherein the optical clear adhesive comprises a light shielding region and a light transmission region, and the light shielding region surrounds the light transmission region.

7. The polarization assembly as claimed in claim 6, wherein the light shielding region is distributed with a light shielding colorant.

8. The polarization assembly as claimed in claim 7, wherein the light shielding colorant is a decomposed colorant.

9. The polarization assembly as claimed in claim 1, wherein the polarizer comprises:
a body; and
a protruding structure formed on at least one side surface of the body;
wherein the protruding structure comprises a plurality of protrusions in nanoscale, a refractive index of a surface of each protrusion varies in continuous gradient.

10. The polarization assembly as claimed in claim 9, wherein the polarizer further comprises a bottom coating layer, the bottom coating layer is disposed between the protrusions and a surface of the body, the bottom coating layer is disposed on the surface of the body, and the protrusions are distributed on the bottom coating layer at intervals.

11. A display device, comprising a display panel, a polarization assembly disposed on the display panel, and a touch panel disposed on the polarization assembly, wherein the polarization assembly comprises:
a polarizer; and
an optical clear adhesive disposed on at least one side surface of the polarizer;
wherein the polarizer and the optical clear adhesive are formed integrally into one piece.

12. The display device as claimed in claim 11, wherein the optical clear adhesive comprises a second optical clear adhesive and a third optical clear adhesive, and the second optical clear adhesive and the third optical clear adhesive are disposed on two opposite side surfaces of the polarizer respectively.

13. The display device as claimed in claim 11, wherein the optical clear adhesive comprises a light shielding region and a light transmission region, and the light shielding region surrounds the light transmission region.

14. The display device as claimed in claim 13, wherein the light shielding region is distributed with a light shielding colorant.

15. The display device as claimed in claim 14, wherein the light shielding colorant is a decomposed colorant.

16. A display device, comprising a display panel, a polarization assembly on the display panel, a cover plate disposed on the polarization assembly, wherein the polarization assembly comprises:
a polarizer; and
an optical clear adhesive disposed on at least one side surface of the polarizer;
wherein the polarizer and the optical clear adhesive are formed integrally into one piece.

17. The display device as claimed in claim 16, wherein the optical clear adhesive comprises a second optical clear adhesive and a third optical clear adhesive, the second optical clear adhesive and the third optical clear adhesive are disposed on two opposite side surfaces of the polarizer.

18. The display device as claimed in claim 16, wherein the optical clear adhesive comprises a light shielding region and a light transmission region, and the light shielding region surrounds the light transmission region.

19. The display device as claimed in claim 16, wherein the polarizer comprises:
a body; and
a protruding structure formed on at least one side surface of the body;
wherein the protruding structure comprises a plurality of protrusions in nanoscale, a refractive index of a surface of each protrusion varies in continuous gradient.

20. The display device as claimed in claim 19, wherein the polarizer further comprises a bottom coating layer, the bottom coating layer is disposed between the protrusions and a surface of the body, the bottom coating layer is disposed on the surface of the body, and the protrusions are distributed on the bottom coating layer at intervals.
